(19) United States
(12) Patent Application Publication
(10) Pub. No.: US 2007/0076357 A1
(43) Pub. Date: Apr. 5, 2007

(54) Casing of electronic device

(75) Inventors: Xin-Yu Zhang, Taipei (TW); Tien-Chang Lin, Taipei (TW)

Correspondence Address: FULBRIGHT AND JAWORSKI LLP, 555 S. FLOWER STREET, 41ST FLOOR, LOS ANGELES, CA, 90071, US

(73) Assignee: INVENTEC CORPORATION

(21) Appl. No.: 11/395,949

(22) Filed: Mar. 30, 2006

(30) Foreign Application Priority Data
Sep. 30, 2005 (TW) 94216924

(51) Int. Cl. H05K 5/00

(52) U.S. Cl. 361/679

(57) ABSTRACT

A casing of an electronic device is proposed, which includes a first casing member having at least an expansion interface slot for being connected with an expansion device, and an opening corresponding to the expansion interface slot; a second casing member covering the first casing member and having a gap corresponding to the expansion interface slot; and a detachable covering member capable of being detachably assembled to the gap of the second casing member, wherein the gap can reduce the fall of level between the casing members and avoid an opening of an expansion interface slot being obstructed due to a downward oblique configuration of the casing, allowing the expansion interface slot of the first casing member to functions normally and avoiding dust from entering into the expansion interface slot, thereby improving the connection and signal transmission quality.

### FIELD OF THE INVENTION

The present invention relates to casings of electronic devices, and more particularly, to a casing of an electronic device formed with two different sizes of casing members allows an expansion interface slot assembled at one of the casing member to function normally without being obstructed the casing.

### BACKGROUND OF THE INVENTION

Following by the development of computer technology, notebook computers have been substituted for desktop computer and become a mainstream in the computer market. Generally, sizes of a notebook computer could be cataloged into two sections, an A4 size and a B5 size. An A4 size is a standard size for a notebook computer, and the size of its keyboard is similar to the size of a keyboard of a desktop computer, thus it is easy to use. Further, most of the A4 notebook computers are packed with a relatively large thin-film transistor liquid-crystal display (TFT-LCD), wherein the screen sizes are at least 12.1 inches (measured diagonally); some even come with a 14 inches LCD or a 15 inches LCD so as to provide a more comfortable environment for a user, who usually use the notebook computer over a continuously long period of time.

Unlike A4 notebook computers, B5 notebook computers are designed for portability, so the overall sizes of the B5 notebook computers are relatively small and the keyboard sizes are reduced; however, it is uncomfortable for users with large hands to use it. Moreover, these relatively small notebook computers are made with relatively small LCDs in size range from 10 to 11 inches, and a few modules of notebook computers have screen sizes smaller than 10 inches.

As a result, the development with regard to the size of the notebook computer is divided into two different ways. For instance, for those notebook computers that are focusing on the portability, mobility, capacity of the battery and battery hours, the panels are made in size range from 12.1 to 14.1 inches, whereas the other kind of notebook computers employed as desktop replacement notebooks are made with relatively larger panels in size range from 14.1 to 15 inches.

In the present computer market, panel with 14.1 inches and 15 inches are becoming mainstream of notebook computer, which is stressed on portability and large screen with preferred visual effect, so various manufacturers issue a variety of types computer with different functions, and fabricate large numbers of cases with a specification such as 14.1 inches and 15 inches, so as to meet requirements of different consumers. Mould must be redesigned and remade when a case of a new type notebook computer is developed, unless the new developed computers have same size and can be applied in the same type of base, for example, case with 14.1 inches can not share with the same type of base with case with 15 inches, mould must be redesigned and remade, which may occupy a great deal of money, labor and time, thus, various manufacturers dedicate themselves to improve it one after the other, an approach for sharing with a same type of base is accordingly developed to make the base form a downward oblique shape, so as to shrink the fall of level between an upper casing member and a lower casing member of the motherboard base, and reduce the fall of level to 3.5 mm, thereby enabling the case with 14.1 inches to share with the same type of base with the case having 15 inches, so as to reduce the fabricating cost, and further save labor as well as time.

Thus, the above-described motherboard base is made into an oblique shape for shrinking the fall of level between the upper and the lower casing members, in order to share a same type of base among different sizes of notebook computer; however, if a PC card (PCMCIA) slot, a peripheral equipment of a notebook computer, is formed at the lower casing member of a 15 inches casing, the PC card slot would be covered by the upper casing member by 3.5 mm, which makes the PC card unable to be used properly.

Accordingly, the problem to be solved herewith is to provide a casing of an electronic device, so as to not only enable the base to be shared among different sizes of electronic device, as well as solving drawbacks of having a PC card that cannot function normally due to the oblique shape of the motherboard base.

### SUMMARY OF THE INVENTION

In light of the above prior-art drawbacks, a primary objective of the present invention is to provide a casing of an electronic device, which could solve problems of having two different sizes of casing members by forming a gap at a second casing member of the electronic device, so as to reduce the fall of level between the casing members and avoid an expansion interface slot being obstructed due to a downward oblique configuration of the casing resulted from the size differences of the two casing members, allowing the expansion interface slot of the first casing member to function normally.

Another objective of the present invention is to provide a casing of an electronic device, which could prevent extraneous materials from entering into a connector slot (i.e. expansion interface slot) and damaging the connector slot, and could further avoid the inner contact terminals from being covered by dust or being rusted by steam, thereby improving the connection and signal transmission quality of the connector.

In accordance with the foregoing and other objectives, the present invention proposes a casing of an electronic device, comprising: a first casing member having at least an expansion interface slot for coupling with an expansion device, and an opening corresponding to the expansion interface slot; a second casing member covering on the first casing member and formed with a gap corresponding to the expansion interface slot for exposing the opening of the first casing member; and a detachable covering member assembled to the gap of the second casing member, wherein the gap allows the expansion device to be inserted into the expansion interface slot without being obstructed by the second casing member.

The models of the foregoing first casing member and the second casing member are different in sizes. Preferably, the second casing member is formed in a relatively long shape, and the first casing member is formed in a relatively short shape, so as to form the body in the shape of a trapezoid.

The gap is formed at the second casing. Preferably, the gap is employed for guiding insertion of the expansion device into the expansion interface slot.

The expansion device may be a PCMCIA card, a SD card, a MMC card, a XD card or a SMC card.

Further, a button is formed at a side of the expansion interface slot, for ejecting the expansion device.

In one embodiment, the detachable covering member comprising a mobile shielding member and at least a coupling portion, is placed at the gap of the second casing member and employed for shielding the expansion interface slot, so as to prevent dust from entering into the expansion interface slot, which could influence signal transmission quality. Preferably, the detachable covering member is made of rubber or plastic materials.

Further, the mobile shielding member is formed with at least a fastening member. Preferably, the fastening members are protrusions or tenon-shaped structures.

An end of the coupling portion is fixed at the mobile shielding member and another end of the coupling portion is coupled to the first casing member in a movable manner, so as to allow the coupling portions to be extended from and retracted back to the first casing member, and connected with the detachable covering member and the second casing member.

Accordingly, the casing of the electronic device of the present invention could overcome drawbacks of having two different sizes of casing members due to the downward oblique configuration of the casing resulted from the size differences of the two casing members, by providing the gap formed at the second casing. This thereby prevents the first casing member from being obstructed by the second casing member, while employing two different sizes of casing members in a single casing. As a result, arrangement as such allows the expansion interface slot of the first casing member to function normally, and prevents extraneous materials from entering into the connector slot and damaging the connector slot, and could further avoid the inner contact terminals from being covered by dust or being rusted by steam, thereby improving the connection and signal transmission quality of the connector.

### BRIEF DESCRIPTION OF DRAWINGS

FIG. 1 is a schematic diagram showing a casing of an electronic device according an embodiment of the present invention;

FIG. 2 is a schematic diagram showing a portion of the structure of the casing of an electronic device case according to the present invention;

FIG. 3 is a schematic diagram showing a detachable covering member of an electronic device case according to another embodiment of the present invention;

FIG. 4A is a schematic side view showing a detachable covering member of an electronic device case according to the present invention;

FIG. 4B is a schematic side view showing the process of opening a detachable covering member of an electronic device case according to the present invention; and

FIG. 4C is a schematic side view showing the completely open state of a detachable covering member of an electronic device case according to the present invention.

### DETAILED DESCRIPTION OF THE PREFERRED EMBODIMENTS

A notebook computer is taken as an example of an electronic device according to embodiments of the present invention. However, it should be understood for those skilled in the art that the electronic device may as well be a PDA, a game machine, a palm computer, a phone and the like.

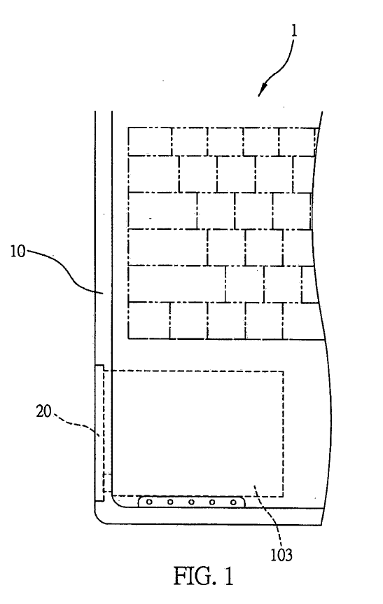

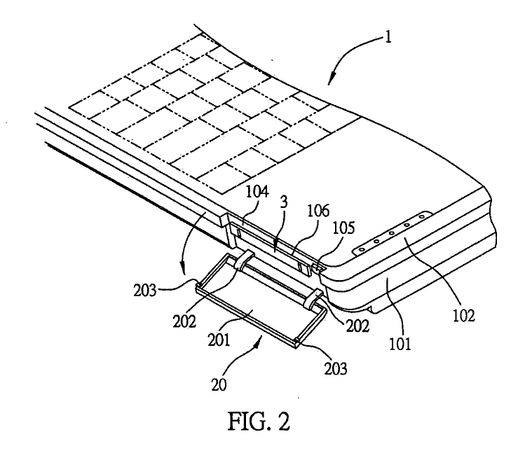

FIG. 1 is a schematic diagram showing a casing of an electronic device such as a notebook computer according an embodiment of the present invention. In one embodiment, the casing 1 of the electronic device according to the present invention, comprises: a body 10 and a detachable covering member 20, wherein the body 10 is formed with a first casing member 101 and a second casing member 102, and the detachable covering member 20 comprises a mobile shielding member 201 and a plurality of coupling portions 202 (as shown in FIG. 2).

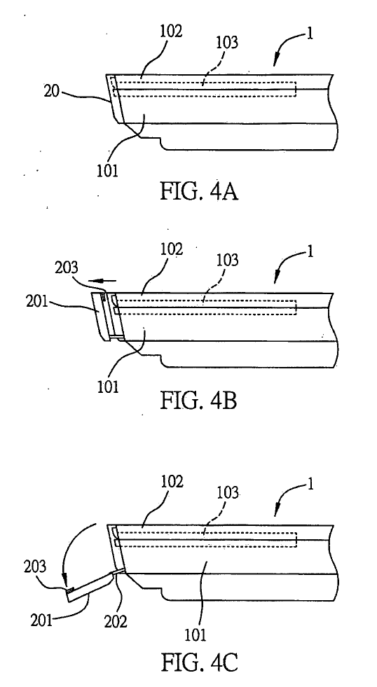

FIG. 2 is a schematic diagram showing a portion of the structure of the casing of an electronic device case according to the present invention. In one embodiment, sizes of the first casing member member 101 and the second casing member 102 of the body 10 are different, wherein the second casing member 102 is formed in a relatively long shape, and the first casing member 101 is formed in a relatively short shape, thereby forming the body 10 in the shape of a trapezoid (as shown in FIG. 4). Further, the first casing member 101 is formed with at least an expansion interface slot 103 for coupling with an expansion device 3, and an opening 106 corresponding to the expansion interface slot 103. The second casing member 102 covering the first casing member 101 is formed with a gap 104 corresponding to the expansion interface slot, so as to expose the opening 106 of the first casing member 101. Further, the gap 104 is also used for guiding insertion of the expansion device 3 into the expansion interface slot 103. Furthermore, a button 105 for ejecting the expansion device 3 is formed at a side of the opening 106 abutted the expansion interface slot 103.

The expansion device 3 may be at least one of a PCMCIA card, a SD card, a MMC card, a XD card and a SMC card.

The detachable covering member 20 is placed at the gap 104 of the second casing member 102, and employed for shielding the opening 106 of the first casing member 101, so as to prevent dust from entering into the expansion interface slot 103, which could influence signal transmission quality. In one embodiment, the detachable covering member 20 may be made of rubber or plastic materials. Further, both sides of the mobile shielding member 201 of the detachable covering member 20 are respectively formed with at least a fastening member 203. In one embodiment, the fastening members 203 may be protrusions or tenon-shaped structures that are coupling to both ends of the gap 104 of the second casing member 102.

The ends of coupling portions 202 of the detachable covering member 20 that are not formed at the mobile shielding member 201, are coupled to the first casing member 101 in a movable manner, so as to allow the coupling portions 202 to be extended from and retracted back to the first casing member 101, while connecting to the detachable covering member 20 and the body 10.

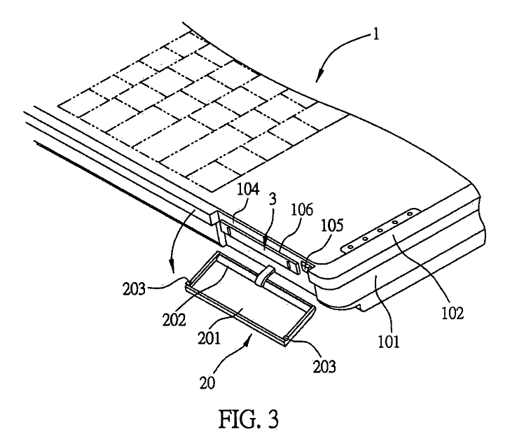

FIG. 3 is a schematic diagram showing a detachable covering member of an electronic device case according to another embodiment of the present invention. In one embodiment, the casing 1 of the electronic device according to the present invention, comprises: a body 10 and a detachable covering member 20, wherein the body 10 is formed with a first casing member 101 and a second casing member 102, and the detachable covering member 20 comprises a mobile shielding member 201 and a coupling portion 202. Further, the coupling portion 202 of the detachable covering member 20 is placed at the centre of the mobile shielding member 201, wherein the coupling portion 202 is employed for connecting the detachable covering member 20 and the body 10. The structures and configurations of the other members are similar to the foregoing embodiment as shown in FIG. 2, and therefore will not be further described hereinafter.

FIGS. 4A through 4C are schematic side views showing the process of pulling out the retracted detachable covering member of a casing of an electronic device case to an extended status according to the present invention. If there is no insertion of the expansion device 3, the detachable covering member 20 is connected to the body 10 via the coupling portion(s) 202 and the fastening members 203, and placed at the gap 104, as shown in FIG. 4A. If the expansion device 3 is to be inserted into the notebook computer, a user could pull or pluck the detachable covering member 20 outward (in the direction of the arrow as shown in FIG. 4) by fingers, so that the fastening member 203 of the mobile shielding member 201 could be released from the fastening portions of the gaps 104 by the force of pulling or plucking, and meanwhile, allowing the coupling portion 202 connecting to the first casing member 101 to be slowly pulled out of the first casing member 101 by the exerting forces, as shown in FIG. 4B. Finally, as shown in FIG. 4C, the detachable covering member 20 could be pulled to a completely open state, so as to allow the expansion device 3 to be inserted into the expansion interface slot 103. This thereby solves the drawbacks of having a downward oblique configuration that may block the opening of the expansion interface slot, due to different sizes of the first casing member and the second casing member. Arrangement as such also provides aesthetics designs and prevents dust from entering.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A casing of an electronic device, comprising:
a first casing member having at least an expansion interface slot for being coupled with an expansion device, and an opening corresponding to the expansion interface slot;
a second casing member covering the first casing member and having a gap corresponding to the expansion interface slot for exposing the opening of the first casing member; and
a detachable covering member detachably assembled to the gap of the second casing member, wherein the gap allows the expansion device to be inserted into the expansion interface slot without being obstructed by the second casing member.

2. The casing of claim 1, wherein the second casing member is formed in a relatively long shape and the first casing member is formed in a relatively short shape, such that the casing has a cross-sectional shape of a trapezoid.

3. The casing of claim 1, wherein the expansion device is at least one of a PCMCIA card, a SD card, a MMC card, a XD card and a SMC card.

4. The casing of claim 1, wherein the gap is for guiding insertion of the expansion device into the expansion interface slot.

5. The casing of claim 3, wherein the gap is for guiding insertion of the expansion device into the expansion interface slot.

6. The casing of claim 1, wherein a button is formed at a side of the expansion interface slot, for ejecting the expansion device.

7. The casing of claim 1, wherein the detachable covering member comprises a mobile shielding member and at least a coupling portion.

8. The casing of claim 7, wherein the mobile shielding member is further formed with at least a fastening member.

9. The casing of claim 8, wherein the fastening member is at least one of a protrusions and a tenon-shaped structure.

10. The casing of claim 7, wherein an end of the coupling portion is fixed at the detachable covering member and another end of the coupling portion is coupled to the first casing member in a movable manner, so as to allow the coupling portion to be extended from and retracted back to the first casing member.

11. The casing of claim 1, wherein the detachable covering member is made of a material selected from the group consisting of rubber and plastic materials.
